(19) United States
(12) Patent Application Publication
(10) Pub. No.: US 2021/0076498 A1
(43) Pub. Date: Mar. 11, 2021

(54) ELECTRONIC DEVICE AND PLATE THEREOF

(71) Applicants: Inventec (Pudong) Technology Corporation, Shanghai (CN); Inventec Corporation, Taipei City (TW)

(72) Inventors: Ming-Hung SHIH, Taipei City (TW); Chun-Ying YANG, Taipei City (TW)

(21) Appl. No.: 16/712,964

(22) Filed: Dec. 12, 2019

(30) Foreign Application Priority Data
Sep. 6, 2019 (CN) 201910841568.9

(51) Int. Cl. H05K 1/14

(52) U.S. Cl. CPC H05K 1/144; H05K 2201/2036; H05K 2201/10409; H05K 2201/042

(57) ABSTRACT

A plate for at least partially covering a first circuit board includes a body portion, at least one first fixing post, at least one second fixing post, and at least one crossing region. The body portion is configured to cover the first circuit board. The first fixing post is connected to a side of the body portion and protrudes from the body portion. The first fixing post is configured to be fixed to the first circuit board. The second fixing post is connected to another side of the body portion and protrudes from the body portion. The second fixing post is configured to be fixed to a second circuit board. The crossing region is disposed on the body portion. The crossing region is configured to allow at least one electronic component on the first circuit board to pass through.

### CROSS-REFERENCE TO RELATED APPLICATION

This application claims priority to China Application Serial Number 201910841568.9, filed Sep. 6, 2019, which is herein incorporated by reference in its entirety.

### BACKGROUND

### Field of Invention

The present invention relates to an electronic device. More particularly, the present invention relates to the electronic device that can accommodate mutual fixation of multilayer circuit boards.

### Description of Related Art

With an advent of technology, functional requirements for an electronic device are increasing. To meet the expectations of the public, a number of circuit board installed in the electronic device is increased also. On the other hand, to simplify the size of the electronic device, a configuration of the plurality of circuit boards is usually disposed in the electronic device in a stacked manner.

Currently, a circuit board above an underlying circuit board is usually screwed to the underlying circuit board. However, a circuit design of each circuit board is different. Therefore, a configuration of locking holes is also different such that the flexibility of the assembly of the electronic device is limited.

Accordingly, how to provide an electronic device to solve the aforementioned problems becomes an important issue to be solved by those in the industry.

### SUMMARY

The invention provides a plate that can accommodate different fixing hole configuration of different circuit boards and an electronic device with the plate.

According to an embodiment of the disclosure, the plate for at least partially covering a first circuit board includes a body portion, at least one first fixing post, at least one second fixing post, and at least one crossing region. The body portion is configured to cover the first circuit board. The first fixing post is connected to a side of the body portion and protrudes from the body portion. The first fixing post is configured to be fixed to the first circuit board. The second fixing post is connected to another side of the body portion and protrudes from the body portion. The second fixing post is configured to be fixed to a second circuit board. The crossing region is disposed on the body portion. The crossing region is configured to allow at least one electronic component on the first circuit board to pass through.

In an embodiment of the disclosure, a material of the plate includes plastic.

In an embodiment of the disclosure, the second fixing post includes a through hole. The through hole penetrates the second fixing post.

In an embodiment of the disclosure, the second fixing post further includes an internal thread portion. The internal thread portion is disposed in the through hole.

In an embodiment of the disclosure, the second fixing post further includes a stud. The stud is disposed in the through hole and the internal thread portion is disposed on an inner wall of the stud.

In an embodiment of the disclosure, a number of the at least one first fixing post is plural.

In an embodiment of the disclosure, a number of the at least one second fixing post is plural.

According to another embodiment of the disclosure, an electronic includes the above plate, a first circuit board, and a second circuit board. The body portion of the plate at least partially covers the first circuit board. The first circuit board is fixed to the plate through the first fixing post. The second circuit board is fixed to the plate through the second fixing post.

In an embodiment of the disclosure, the first circuit board has at least one electronic component. The electronic component passes through the crossing region of the plate.

In an embodiment of the disclosure, the plate has a fixing hole. The fixing hole penetrates through the first fixing post and the body portion. The fixing hole is a countersunk hole.

In an embodiment of the disclosure, an end of the first fixing post away from the body portion is abutted to a board surface of the first circuit board. An end of the second fixing post away from the body portion is abutted to a board surface of the second circuit board.

Accordingly, in the electronic device of the present disclosure, the plate is disposed between the two circuit boards and the two circuit boards are fixed to each other by the plate. Two sides of the plate have at least one first fixing post and at least one second fixing post, respectively. The two circuit boards are fixed to the two sides of the plate by the first fixing post and the second fixing post, respectively. Positions of the first fixing post and the second fixing post can be disposed according to positions of fixing holes of the two circuit boards. As such, the flexibility of assembly of the electronic device can be increased. In addition, the plate protects the electronic components on the underlying circuit board from damage to the electronic components on the underlying circuit board when the locking tool locks the plate and the circuit boards.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a partial perspective view of an electronic device according to an embodiment of the disclosure;

FIG. 2 is a partial enlarge view of the electronic device in a broken line frame C in FIG. 1; and

FIG. 3 is a partial cross-sectional view of the electronic device taken along line 3-3 in FIG. 1.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

In addition, terms used in the specification and the claims generally have the usual meaning as each terms are used in the field, in the context of the disclosure and in the context of the particular content unless particularly specified. Some terms used to describe the disclosure are to be discussed below or elsewhere in the specification to provide additional guidance related to the description of the disclosure to specialists in the art.

Phrases “first,” “second,” etc., are solely used to separate the descriptions of elements or operations with same technical terms, not intended to be the meaning of order or to limit the invention.

Secondly, phrases “comprising,” “includes,” “provided,” and the like, used in the context are all open-ended terms, i.e. including but not limited to.

Further, in the context, “a” and “the” can be generally referred to one or more unless the context particularly requires. It will be further understood that phrases “comprising,” “includes,” “provided,” and the like, used in the context indicate the characterization, region, integer, step, operation, element and/or component it stated, but not exclude descriptions it stated or additional one or more other characterizations, regions, integers, steps, operations, elements, components and/or groups thereof.

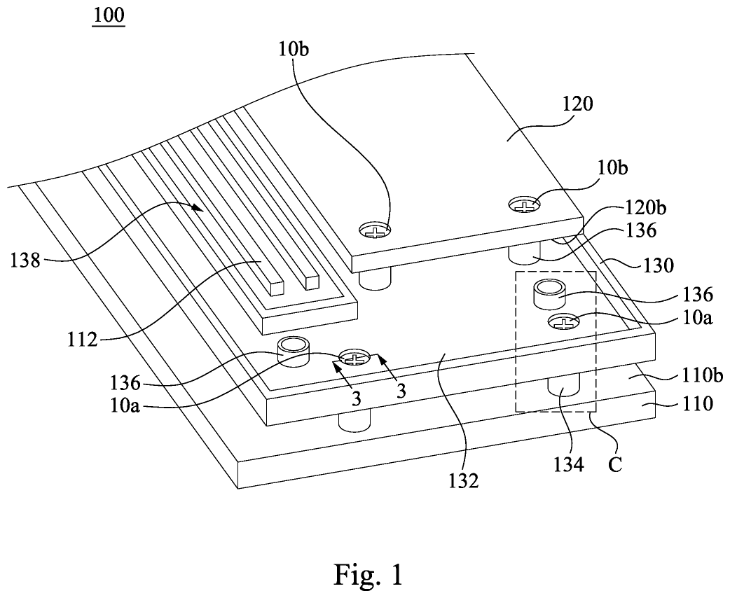

Reference is made to FIG. 1. FIG. 1 is a partial perspective view of an electronic device 100 according to an embodiment of the disclosure. As shown in FIG. 1, the electronic device 100 of the disclosure can be a computer device such as a computer or a server, but the disclosure is not limited in this regard. The electronic device 100 includes a first circuit board 110, a second circuit board 120, and a plate 130. The plate 130 at least partially covers the first circuit board 110. The second circuit board 120 is disposed on the plate 130. In other words, the plate 130 is located between the first circuit board 110 and the second circuit board 120. The second circuit board 120 is fixed to the first circuit board 110 through the plate 130.

In some embodiments, the material of the plate 130 includes plastic or insulating material, but the disclosure is not limited in this regard. As such, the plate 130 can prevent the first circuit board 110 and the second circuit board 120 from being electrically interfered by each other due to being too close to each other.

The plate 130 includes a body portion 132, a plurality of first fixing post 134 (only one is shown in the figure due to the perspective), a plurality of second fixing post 136, and a crossing region 138. The first fixing post 134 is connected to a side of the body portion 132 close to the first circuit board 110, and protrudes from the body portion 132 toward the first circuit board 110. The second fixing post 136 is connected to a side of the body portion 132 away from the first circuit board 110, and protrudes from the body portion 132 away from the first circuit board 110.

Further, an end of the first fixing post 134 is abutted against a board surface 110b of the first circuit board 110. An end of the second fixing post 136 is abutted against a board surface 120b of the second circuit board 120. The first fixing post 134 is configured to be fixed to the first circuit board 110. The second fixing post 136 is configured to be fixed to the second circuit board 120. The crossing region 138 is disposed on the body portion 132. In the embodiment, the crossing region 138 is a long slot, but the disclosure should not be limited in this regard. Electronic components 112 on the first circuit board 110 can pass through the crossing region 138 and be exposed by the crossing region 138.

With the configuration described above, the first fixing post 134 can raise the body portion 132 such that the body portion 132 is distanced from the board surface 110b of the first circuit board 110, so as to prevent the body portion 132 from crushing circuits or electronic elements on the first circuit board 110. Likewise, the second fixing post 136 can raise the second circuit board 120 to prevent the second circuit board 120 from colliding with the electronic components 112 on the first circuit board 110. In addition, the body portion 132 can protect the circuits and the electronic elements on the first circuit board 110 to prevent the circuits and the electronic elements from being damaged by crashing of other objects.

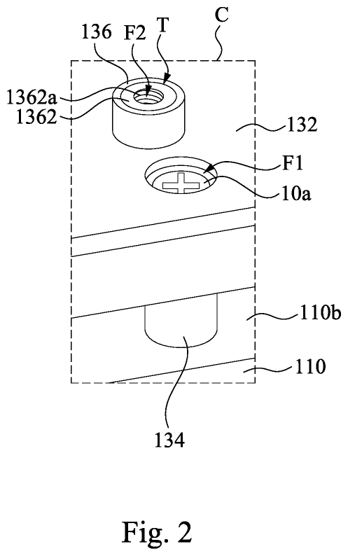

Reference is made to FIG. 2. FIG. 2 is a partial enlarge view of the electronic device 100 in a broken line frame C in FIG. 1. As shown in FIG. 2, the plate 130 has a first fixing hole F1 and a second fixing hole F2. The first fixing hole F1 penetrates the body portion 132 and the first fixing post 134. The first fixing hole F1 can be passed through by a locking element 10a to fix the first circuit board 110 to the first fixing post 134. The second fixing hole F2 at least partially extends into the second fixing post 136. The second fixing hole F2 is passed through by a locking element 10b to fix the second circuit board 120 to the second fixing post 136, as shown in FIG. 1.

Specifically, in the embodiment, the second fixing post 136 includes a hole T and a stud 1362. The stud 1362 is disposed in the hole T. The second fixing hole F2 is located in the stud 1362. The stud 1362 includes an internal thread portion 1362a. The internal thread portion 1362a is disposed on an inner wall of the stud 1362. In the embodiment, the locking element 10b is a screw having an external thread portion. As such, the locking element 10b can be fixed to the second fixing post 136 by meshing the external thread portion of the locking element 10b to the internal thread portion 1362a of the stud 1362. Further, the locking element 10b is fixed to the second fixing post 136 after it passes through the locking hole on the second circuit board 120. As such, the second circuit board 120 is fixed to the second fixing post 136.

In some embodiments, the hole T is a through hole. In other embodiments, the hole T is a blind hole. The disclosure should not be limited in this regard.

In some embodiments, the inner wall of the second fixing post 136 has an internal thread. The locking element 10b can be directly meshed with the internal thread on the inner wall of the second fixing post 136. In other embodiments, the stud 1362 in the hole T can be selectively dispensed. In such other embodiments, the locking element 10b is a self-tapping screw. As such, the locking element 10b can be directly meshed with the inner wall of the hole T and thereby be fixed in the second fixing post 136 when the locking element 10b is drilled into the hole T. However, the disclosure should not be limited in this regard.

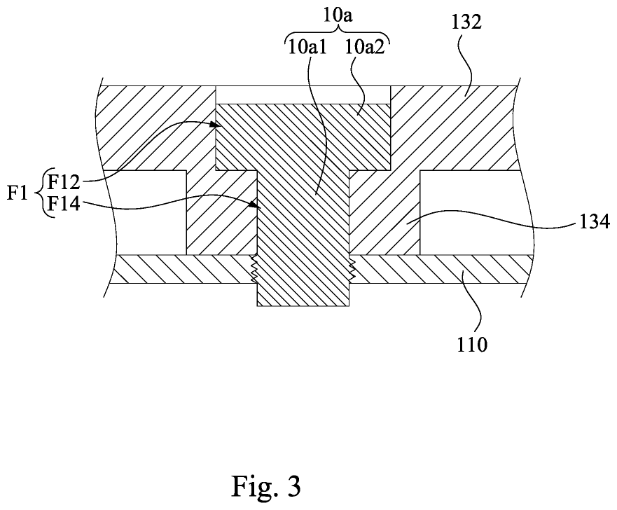

Reference is made to FIG. 3. FIG. 3 is a partial cross-sectional view of the electronic device 100 taken along line 3-3 in FIG. 1. As shown in FIG. 3, in the embodiment, the first fixing hole F1 is a countersunk hole. The first fixing hole F1 includes a countersinking portion F12 and a penetrating portion F14. The countersinking portion F12 communicates with the penetrating portion F14. The countersinking portion 1342 is formed by a recess of the body portion 132 away from the first circuit board 110. The locking element 10a includes a cap portion 10a1 and a cylinder 10a2. The cap portion 10a1 is located in the countersinking portion F12 of the first fixing hole F1. The cap portion 10a1 is abutted against a top surface of the first fixing post 134 that is a bottom surface of the countersinking portion F12. The cylinder 10a2 is located in the penetrating portion F14 of the first fixing hole F1 and extends into a locking hole of the first circuit board 110. As such, when the locking element 10a passes through the first fixing hole F1 and is locked with the locking hole of the first circuit board 110, the first fixing post 134 can be fixed to a position between the locking element 10a and the first circuit board 110.

In some embodiments, the first fixing post F1 is not the countersunk hole. In other words, in such embodiments, the first fixing post F1 is a pure through hole. The locking element 10a penetrates into the first fixing hole F1. The cap portion 10a1 of the locking element 10a is abutted to a surface of the body portion 132 away from the first circuit board 110. The disclosure is not limited in this regard.

In some embodiments, lengths of the first fixing post 134 and the second fixing post 136 extending relative to the body portion 132 can be adjusted according to actual needs. The disclosure is not limited in this regard.

In some embodiments, numbers and positions of the first fixing post 134 and the second fixing post 136 can be adjusted according to actual needs. The disclosure is not limited in this regard. Specifically, the numbers and the positions of the first fixing post 134 and the second fixing post 136 can be disposed in cooperation with the locking holes of the first circuit board 110 and the second circuit board 120 to improve the flexibility of assembly of the electronic device 100.

According to the foregoing recitations of the embodiments of the disclosure, it can be seen that in the electronic device of the present disclosure, the plate is disposed between the two circuit boards and the two circuit boards are fixed to each other by the plate. Two sides of the plate have at least one first fixing post and at least one second fixing post, respectively. The two circuit boards are fixed to the two sides of the plate by the first fixing post and the second fixing post, respectively. Positions of the first fixing post and the second fixing post can be disposed according to positions of fixing holes of the two circuit boards. As such, the flexibility of assembly of the electronic device can be increased. In addition, the plate protects the electronic components on the underlying circuit board from damage to the electronic components on the underlying circuit board when the locking tool locks the plate and the circuit boards.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A plate for at least partially covering a first circuit board, the plate comprising:
a body portion configured to cover the first circuit board;
at least one first fixing post connected to a side of the body portion, protruding relative to the body portion, and configured to be fixed to the first circuit board;
at least one second fixing post connected to another side of the body portion, protruding relative to the body portion, and configured to be fixed to a second circuit board; and
at least one crossing region configured to allow at least one electronic component on the first circuit board to pass through.

2. The plate of claim 1, wherein a material of the plate comprises plastic.

3. The plate of claim 1, wherein the second fixing post comprises a through hole penetrating the second fixing post.

4. The plate of claim 3, wherein the second fixing post further comprises an internal thread portion disposed in the through hole.

5. The plate of claim 4, wherein the second fixing post further comprises a stud disposed in the through hole and the internal thread portion is disposed on an inner wall of the stud.

6. The plate of claim 1, wherein a number of the at least one first fixing post is plural.

7. The plate of claim 1, wherein a number of the at least one second fixing post is plural.

8. An electronic device, comprising:
a plate comprising:
a body portion;
at least one first fixing post connected to a side of the body portion and protruding relative to the body portion; and
at least one second fixing post connected to another side of the body portion and protruding relative to the body portion;
a first circuit board, wherein the body portion of the plate at least partially covers the first circuit board and the first circuit board is fixed to the plate through the first fixing post; and
a second circuit board, wherein the second circuit board is fixed to the plate through the second fixing post.

9. The electronic device of claim 8, wherein the first circuit board has at least one electronic component, the plate further comprises at least one crossing region, and the electronic component passes through the crossing region.

10. The electronic device of claim 8, wherein the plate has a fixing hole penetrating through the first fixing post and the body portion, and the fixing hole is a countersunk hole.

11. The electronic device of claim 8, wherein an end of the first fixing post away from the body portion is abutted to a board surface of the first circuit board and an end of the second fixing post away from the body portion is abutted to a board surface of the second circuit board.

12. The electronic device of claim 8, wherein a material of the plate comprises plastic.

13. The electronic device of claim 8, wherein the second fixing post comprises a through hole penetrating the second fixing post.

14. The electronic device of claim 13, wherein the second fixing post further comprises an internal thread portion disposed in the through hole.

15. The electronic device of claim 14, wherein the second fixing post further comprises a stud disposed in the through hole and the internal thread portion is disposed on an inner wall of the stud.

16. The electronic device of claim 8, wherein a number of the at least one first fixing post is plural.

17. The electronic device of claim 8, wherein a number of the at least one second fixing post is plural.
